(19) United States
(12) Patent Application Publication
(10) Pub. No.: US 2007/0240980 A1
(43) Pub. Date: Oct. 18, 2007

(54) Sputtering target and sputtering equipment

(75) Inventors: Guan-Yeu Chu, Taichung City (TW); Chin-Pei Hwang, Taichung City (TW); Yi-Shu Chen, Taichung City (TW); Kun-Feng Lin, Taichung County (TW)

Correspondence Address: BACON & THOMAS, PLLC, 625 SLATERS LANE, FOURTH FLOOR, ALEXANDRIA, VA, 22314, US

(73) Assignee: WINTEK CORPORATION, TAICHUNG (TW)

(21) Appl. No.: 11/599,986

(22) Filed: Nov. 16, 2006

(30) Foreign Application Priority Data
Apr. 12, 2006 (TW) 95113046

(51) Int. Cl. C23C 14/00

(52) U.S. Cl. 204/298.12

(57) ABSTRACT

A sputtering target having at least one flat first sputtering surface and at least one second sputtering surfaces respectively and laterally abutted against the flat first sputtering surface and slanting in one direction relative to the first sputtering surface. By means of adjusting the position of the second sputtering surface related to the first sputtering surface and utilizing the differently slanted second sputtering surface of the sputtering target, the distribution of the thin film deposited on the surfaced of a substrate is relatively controlled and a uniform thickness of the thin film is obtained.

### BACKGROUND OF THE INVENTION

1. Field of the Invention

The present invention relates to sputtering equipment and more specifically, to a sputtering target, which is practical for use to deposit a uniform thickness thin film on a substrate by sputtering technique.

2. Description of the Related Art

PVD (Physical Vapor Deposition) technology includes vacuum evaporation technique and sputtering technique. Because sputtering technique is practical for the large area deposition, it is commonly employed in the fabrication of TFT-LCD (Thin Film Transistor Liquid Crystal Display) to deposit a thin conductive film of ITO (Indium Tin Oxide) on a glass substrate.

FIG. 4 shows the basic principle of sputtering technique. As illustrated, a sputtering target 90 and a substrate 92 are put in a vacuum environment, keeping the sputtering target 90 arranged on the side of a high-voltage cathode 94 and the substrate 92 on the side of a high-voltage anode 96, and then the plasma which is induced from a glow discharge between the cathode 94 and the anode 96 is used to cause a sputtering gas in between the sputtering target 90 and the substrate 92 to produce positive ions, which are then attracted by the high-voltage cathode 94 to bombard the sputtering target 90 so that atoms or molecules of the sputtering target 90 are bombarded out and deposited on the surface of the substrate 92, forming a thin-film deposition on the substrate 92.

During sputtering process, low ionization degree of gas molecules will result in a low sputtering rate. Therefore, a magnetic field 98 will generally be provided inside the cathode 94. When the electrons discharged from the cathode 94 are accelerated by the magnetic field, the magnetic field also causes the electrons to move spirally, thereby increasing the moving path of the electrons. Increasing the moving path of the electrons relatively increases the chance of ionization degree of gas molecules, thereby forming a relatively higher concentration of plasma and a relatively more stable glow discharge to accelerate the growing speed of the thin-film deposition.

When using the aforesaid magnetic field-added sputtering method to deposit multiple substrates or a large area substrate, it is difficult to keep the magnetic field evenly distributed in the region to deposit, and the thin-film deposition thus formed on the substrate will have an uneven thickness. Further, the thickness of the thin-film deposition at the two distal ends of the substrate will be relatively thinner because there is a limitation to the size of the sputtering equipment and the length of the cathode under the consideration of cost.

In order to improve the uneven thin-film thickness problem, a trimming shield may be added and set between the sputtering target and the substrate corresponding to the relatively thicker area of the thin-film to stop the atoms or molecules been bombarded out of the corresponding area of the sputtering target from depositing on the substrate so that a uniform thickness of thin film deposition can finally be obtained. However, this method of using the trimming shield during sputtering process will waste much sputtering target material and will also affect the deposition speed and productivity. Further, a big amount of the sputtering target material will be deposited on the trimming shield. When the sputtering target material is peeling off from the trimming shield, it will contaminate the sputtering equipment. Therefore, the sputtering equipment must be frequently cleaned during fabrication, thereby increasing the manufacturing cost.

### SUMMARY OF THE INVENTION

The present invention has been accomplished under the circumstances in view. It is therefore the main object of the present invention to provide a sputtering target, which is practical for use to deposit a thin film having a uniform thickness on a substrate by sputtering technique.

To achieve this and other objects of the present invention, the sputtering target has at least one first sputtering surface, and at least one second sputtering surface abutted against the first sputtering surface laterally and slanting in one direction relative to the first sputtering surface. By means of adjusting the position of the second sputtering surface related to the first sputtering surface and utilizing the differently slanted second sputtering surfaces of the sputtering target, the atoms of the sputtering target can be dispersed to other areas when forming the thin film on the substrate, enabling the originally relatively thicker area to compensate for the originally relatively thinner area, and therefore a uniform thickness of thin film can be coated on the substrate as desired.

### BRIEF DESCRIPTION OF THE DRAWINGS

FIG. 1 is a schematic drawing of a first embodiment of the present invention.

FIG. 2 is a chart showing film thickness distribution curves before and after improvement according to the present invention.

FIG. 3 is a schematic drawing of a second embodiment of the present invention.

FIG. 4 is a schematic drawing showing a sputtering method according to the prior art.

### DETAILED DESCRIPTION OF THE INVENTION

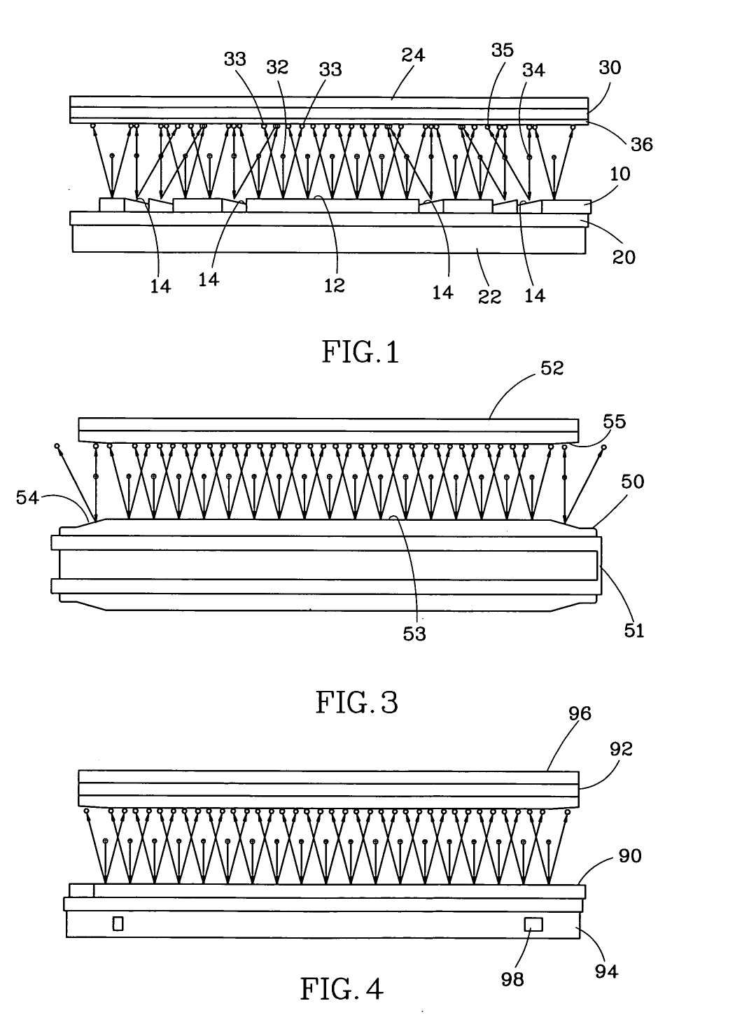

Referring to FIG. 1, a sputtering target 10 in accordance with a first embodiment of the present invention is shown mounted in the cathode 22 of a sputtering equipment by means of a back plate 20. The sputtering target 10 and the back plate 20 may be fastened together by clamping or bonding. The sputtering equipment has a substrate 30 at the anode 24 thereof. The cathode 22, anode 24, back plate 20 of the sputtering equipment are mounted in the housing of the sputtering equipment that is kept in a vacuum status. The sputtering target 10 has at least one first sputtering surface 12 and at least one second sputtering surface 14 corresponding to the substrate 30. The first sputtering surfaces 12 and the second sputtering surfaces 14 are respectively made by laser processing or machine processing. Each first sputtering surface 12 is a flat surface. Each second sputtering surface 14 slants in one direction relative to the first sputtering surface 12. The second sputtering surfaces 14 are abutted against the first sputtering surfaces 12. In one example of the invention, a plurality of second sputtering surfaces are arranged in series at a lateral side of one first sputtering surface. In another example of the invention, at least a first sputtering surface 12 is arranged between two second sputtering surfaces 14.

When using the sputtering target 10 to deposit the thin film on the surface of the substrate 30 by a sputtering technique, positive ions produced between the anode 24 and the cathode 22 bombard each first sputtering surface 12 and second sputtering surface 14 of the sputtering target 10 by the attraction of the cathode 22, thereby causing the atoms or molecules of the sputtering target 10 to be bombarded out and deposit on the surface of the substrate 30 to form a thin film 36. For example, the positive ions, referenced by 32 in FIG. 1, bombard the flat first sputtering surface 12 of the sputtering target 10, the atoms 33 that are bombarded out of the sputtering target 10 are ejected onto the surface of the substrate 30 that faces the first sputtering surface 12, and therefore the deposition position of the atoms 33 corresponds to the bombarding position of the positive ions 32. When the positive ions, referenced by 34 in FIG. 1, bombard the slanted second sputtering surface 14 of the sputtering target 10, the atoms 35 that are bombarded out of the sputtering target 10 are ejected onto the substrate 30 obliquely, and the deposition position of the atoms 35 on the substrate 30 deviates from the bombarding position of the atoms 33. Thereby, by means of changing the relative positions of the first spurting surface 12 and the second sputtering surface 14 and the slant angle of each second sputtering surface 14 relative to the first sputtering surface 12, the distribution of the thin film 36 on the surface of the substrate 30 is relatively controlled.

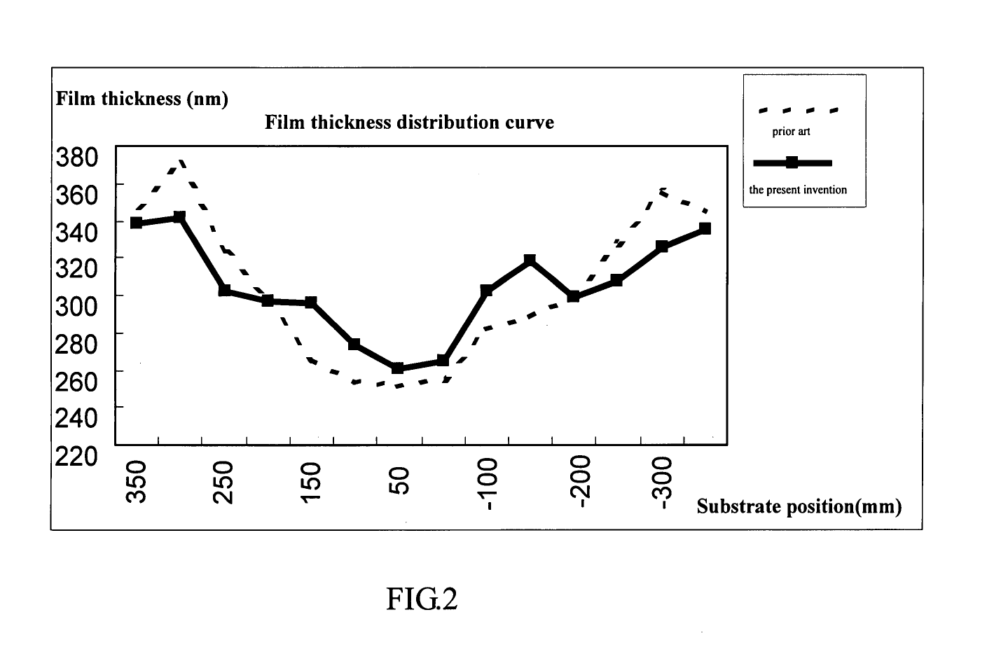

By means of adjusting the position of the second sputtering surface related to the first sputtering surface and utilizing the differently slanted second sputtering surfaces 14 of the sputtering target 10, the atoms of the sputtering target 10 can be dispersed to other areas when forming the thin film 36 on the substrate 30, enabling the originally relatively thicker area to compensate for the originally relatively thinner area. As shown in FIG. 2, the curve 40 illustrates the distribution of film thickness of the thin film 36 formed by using the sputtering target 10; the curve 42 illustrates the distribution of film thickness of a thin film formed by using a conventional sputtering target without any second sputtering surface. As illustrated, the thin film formed by using a conventional sputtering target without any second sputtering surface has a relatively thicker film thickness at the left and right area and a relatively thinner film thickness at the middle area; the invention reduces the film thickness at the left and right side area and increases the film thickness at the middle area, thereby keeping the thin film 36 at a substantially uniform thickness.

Further, when using the sputtering target 10 of the present invention to perform a multi-substrate depositing work or a large-area single-substrate depositing work, it is not necessary to increase the length of the cathode and the size of the sputtering equipment as adapted in the prior art method in order to make the film thickness even. Further, because the first sputtering surface of the aforesaid first embodiment of the present invention is an interrupted structure (multi-segment structure), the arrangement between the first sputtering surface and the second sputtering surface can be made in any of a variety of forms for different applications. Further, the use of the sputtering target 10 eliminates the use of a trimming shield as seen in the prior art design to uniform the distribution of the thin film, thereby reducing pollution problems, extending sputtering equipment cleaning cycle and simplifying the manufacturing process.

The sputtering target of the present invention may be changed subject to different conditions of use. FIG. 3 shows a sputtering target 50 in accordance with a second embodiment of the invention. The sputtering target 50 is a cylindrical member joined to a cylindrical base tube 51. The sputtering target 50 has a flat first sputtering surface 53 disposed at the middle area and facing the substrate 52, and a second sputtering surface 54 extending around the periphery of the border area of the first sputtering surface 53. Further, there is a predetermined slant angle between the first sputtering surface 53 and the second sputtering surfaced 54, therefore, a part of the sputtering target 50 shows a conical structure. By means of the first sputtering surface 53 and the second sputtering surface 54, the uniformity of the thickness of the thin film 55 formed on the substrate 52 is improved.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A sputtering target having at least one first sputtering surface, and at least one second sputtering surface abutted against the first sputtering surface and slanting in one direction relative to the first sputtering surface.

2. The sputtering target as claimed in claim 1, wherein the second sputtering surface is disposed at one lateral side of the first sputtering surface.

3. The sputtering target as claimed in claim 1, wherein the second sputtering surface is disposed at the border of the first sputtering surface, defined a predetermined slant angle relative to the first sputtering surface.

4. The sputtering target as claimed in claim 1, wherein a plurality of the second sputtering surfaces are connected to one another and disposed at the lateral side of the first sputtering surface.

5. The sputtering target as claimed in claim 1, wherein the sputtering target comprising a plurality of the second sputtering surfaces spaced from one another and respectively separated by the at least one first sputtering surface.

6. The sputtering target as claimed in claim 1, which is clamped to a back plate.

7. The sputtering target as claimed in claim 1, which is bonded to a back plate.

8. A sputtering equipment comprising:
a housing;
two electrodes separately arranged inside the housing;
a back plate mounted on one of the two electrodes; and
a sputtering target mounted on the back plate, the sputtering target having at least one first sputtering surface and at least one second sputtering surface abutted against the first sputtering surface and slanting in one direction relative to the first sputtering surface.

9. The sputtering equipment as claimed in claim 8, wherein the second sputtering surface of the sputtering target is disposed at one lateral side of the first sputtering surface.

10. The sputtering equipment as claimed in claim 8, wherein the second sputtering surface of the sputtering target is disposed at the border of the first sputtering surface, defined a predetermined slant angle relative to the first sputtering surface.

11. The sputtering equipment as claimed in claim 8, wherein a plurality of the second sputtering surface of the sputtering target are connected to one another and disposed at one lateral side relative to the first sputtering surface.

12. The sputtering equipment as claimed in claim 8, wherein the sputtering target comprising a plurality of the second sputtering surfaces spaced from one another and respectively separated by the at least one first sputtering surface.

13. The sputtering equipment as claimed in claim 8, wherein the sputtering target is clamped to the back plate.

14. The sputtering equipment as claimed in claim 8, wherein the sputtering target is bonded to the back plate.
